(19) United States
(12) Patent Application Publication
(10) Pub. No.: US 2010/0265678 A1
(43) Pub. Date: Oct. 21, 2010

(54) ENHANCING ADHESION OF MOLDING MATERIALS WITH SUBSTRATES

(75) Inventors: Jitender Pratap Singh, New Delhi (IN); Vijay Malhi, New Delhi (IN)

Correspondence Address: DAVID A. GUERRA;INTERNATIONAL PATENT GROUP, LLC, Suite 700, 1816 Crowchild Trail N.W., CALGARY, AB, T2M 3Y7, CA

(73) Assignee: MOSER BAER INDIA LIMITED, New Delhi (IN)

(21) Appl. No.: 12/625,775

(22) Filed: Nov. 25, 2009

(30) Foreign Application Priority Data
Apr. 20, 2009 (IN) 899/CHE/2009
Apr. 22, 2009 (IN) 936/CHE/2009
Apr. 29, 2009 (IN) 998/CHE/2009

(51) Int. Cl. H05K 5/00; B29C 45/02

(52) U.S. Cl. 361/757; 264/265; 361/752

(57) ABSTRACT

A method of enhancing adhesion of a molding material with a substrate is provided. The method includes forming one or more perforations on a substrate, forming a coat of an affinitive material on at least one of the perforations, and filling the molding material in the perforations. The affinitive material has an affinity for the molding material. Therefore, the molding material adheres to the coat of the affinitive material.

### CROSS-REFERENCE TO RELATED APPLICATION

This application claims the benefit of priority under 35 U.S.C 119 to co-pending India Patent Application No. 998/CHE/2009 filed on Apr. 29, 2009, India Patent Application No. 936/CHE/2009 filed on Apr. 22, 2009, and India Patent Application No. 899/CHE/2009 filed on Apr. 20, 2009. The entire disclosure of the prior applications is incorporated herein by reference.

### BACKGROUND OF THE INVENTION

1. Field of the Invention

The embodiments herein relate, in general, to encapsulation techniques. More particularly, the embodiments relate to a method of enhancing adhesion of a molding material with a substrate.

2. Description of the Prior Art

Universal Serial Bus (USB) flash drives are more common these days than any other portable storage devices. A USB flash drive is typically manufactured using Surface Mount Technology (SMT) in which a flash Integrated Circuit (IC) and other supporting electrical components are mounted on a Printed Circuit Board (PCB). Various components of the USB flash drive are then encapsulated by molding a molding material over the PCB. However, conventional encapsulation techniques often fail to properly encapsulate the various components of the USB flash drive, largely due to inadequate adhesion of the molding material to the PCB. This makes such USB flash drives prone to damage, and therefore, loss of data, due to presence of moisture or water. The problem of poor adhesion becomes more prominent when the USB flash drive is miniaturized, due to limited availability of surface area for adhesion. This leads to higher probability of loss of data, and makes the USB flash drive unusable over a period of time.

In light of the foregoing discussion, there is a need for an encapsulation technique that assists in increasing reliability of storage devices, specially miniaturized storage devices. In this regard, the present invention substantially fulfills this need. In this respect, the encapsulation technique according to the present invention substantially departs from the conventional concepts and designs of the prior art, and in doing so provides a technique primarily developed for the purpose of providing highly reliable storage devices, compared to conventional storage devices.

### SUMMARY OF THE INVENTION

In view of the foregoing disadvantages inherent in the known types of storage devices now present in the prior art, the present invention provides an improved storage device, and overcomes the above-mentioned disadvantages and drawbacks of the prior art. As such, the general purpose of the present invention, which will be described subsequently in greater detail, is to provide a new and improved storage device and method which has all the advantages of the prior art mentioned heretofore and many novel features that result in a storage device which is not anticipated, rendered obvious, suggested, or even implied by the prior art, either alone or in any combination thereof.

An embodiment relates to a method of enhancing adhesion of a molding material with a substrate.

Another embodiment relates to a storage device that is highly reliable, shock resistant, water resistant and robust, compared to conventional storage devices.

Yet another embodiment relates to a storage device that is miniature in size, compared to conventional storage devices.

Embodiments herein provide a method of enhancing adhesion of a molding material with a substrate. The method includes forming one or more perforations on a substrate, forming a coat of an affinitive material on at least one of the perforations, and filling the molding material in the perforations. The affinitive material has an affinity for the molding material. Therefore, the molding material adheres to the coat of the affinitive material. Consequently, adhesion of the molding material to the substrate is enhanced.

In accordance with an embodiment herein, the perforations may have a shape that is curved, polygonal, or a combination thereof. The size of the perforations may, for example, depend on the size of the substrate. The size of the perforations may also depend on the number, the size and the location of various components to be placed on the substrate. In addition, the size of the perforations may depend on their location on the substrate.

In accordance with an embodiment herein, the perforations are formed at preset locations on the substrate. For example, the perforations may be located at a periphery of the substrate.

In accordance with an embodiment herein, the molding material includes at least one of: epoxy resin, silicone, acrylic and polyurethane. As mentioned above, the affinitive material has an affinity for the molding material. Accordingly, a suitable affinitive material may be chosen depending on the molding material to be used. In accordance with an embodiment herein, the affinitive material includes at least one of: silver, silver alloy, copper, copper alloy, nickel, nickel alloy, palladium, gold, gold alloy, and black oxide.

In one embodiment herein, a Chip-On-Board (COB) type storage device is manufactured by a COB process. Electrical components of the COB type storage device are encapsulated by a molding material hermetically, using the above-mentioned method. This makes the COB type storage device highly reliable, shock resistant, water resistant and robust.

As the COB process requires less space, a base substrate of a small size may be used. The COB type storage device so manufactured is miniature in size, and therefore, is easy to handle and use.

There has thus been outlined, rather broadly, the more important features of the invention in order that the detailed description thereof that follows may be better understood and in order that the present contribution to the art may be better appreciated.

Numerous objects, features and advantages of the present invention will be readily apparent to those of ordinary skill in the art upon a reading of the following detailed description of presently preferred, but nonetheless illustrative, embodiments of the present invention when taken in conjunction with the accompanying drawings. In this respect, before explaining the current embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of descriptions and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

These together with other objects of the invention, along with the various features of novelty that characterize the invention, are pointed out with particularity in the claims annexed to and forming a part of this disclosure. For a better understanding of the invention, its operating advantages and the specific objects attained by its uses, reference should be had to the accompanying drawings and descriptive matter in which there are illustrated preferred embodiments of the invention.

### BRIEF DESCRIPTION OF DRAWINGS

Embodiments herein will hereinafter be described in conjunction with the appended drawings provided to illustrate and not to limit the scope of the claims, wherein like designations denote like elements, and in which:

FIGS. 1A and 1B depict top and front views of a base substrate, in accordance with an embodiment herein;

FIGS. 2A and 2B depict top and front views of the base substrate, in accordance with an embodiment herein;

FIGS. 3A and 3B depict top and front views of the base substrate, in accordance with an embodiment herein;

FIGS. 4A and 4B depict top and front views of a base substrate, in accordance with another embodiment herein;

FIGS. 5A and 5B depict top and front views of the base substrate, in accordance with another embodiment herein;

FIGS. 6A and 6B depict top and front views of the base substrate, in accordance with another embodiment herein;

FIG. 7 depicts a system for enhancing adhesion of a molding material with a substrate, in accordance with an embodiment herein;

FIG. 8 illustrates a method of enhancing adhesion of a molding material with a substrate, in accordance with an embodiment herein;

FIG. 9 depicts a system for manufacturing a storage device, in accordance with an embodiment herein;

FIG. 10 depicts a system for manufacturing a storage device, in accordance with another embodiment herein;

FIG. 11 depicts a method of manufacturing a storage device, in accordance with an embodiment herein; and

FIG. 12 depicts a method of manufacturing a storage device, in accordance with another embodiment herein.

### DETAILED DESCRIPTION

As used in the specification and claims, the singular forms “a”, “an” and “the” include plural references unless the context clearly dictates otherwise. For example, the term “a perforation” may include a plurality of perforations unless the context clearly dictates otherwise.

Embodiments herein provide a method of enhancing adhesion of a molding material with a substrate, and articles manufactured thereof. In the description of the embodiments herein, numerous specific details are provided, such as examples of components and/or mechanisms, to provide a thorough understanding of embodiments herein. One skilled in the relevant art will recognize, however, that an embodiment herein can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments herein.

### GLOSSARY

Base substrate: A base substrate is a substrate that provides mechanical support. The base substrate may, for example, be an electronic substrate that provides electrical connectivity. Examples of the base substrate include, but are not limited to, Printed Circuit Boards (PCBs), hybrid microcircuits, and extended PCBs. An extended PCB is a PCB including one or more conductive strips capable of facilitating a Universal Serial Bus (USB) connection.

First surface and second surface: A base substrate has a first surface and a second surface. In accordance with an embodiment herein, the first surface is on an opposite side of the second surface. For example, in case when the base substrate is a PCB, the first surface may be the top surface on which electrical components are placed, while the second surface may be the bottom surface of the base substrate.

Perforation: A perforation is a three-dimensional region formed on a base substrate. A perforation may, for example, be a hole through a base substrate. Alternatively, a perforation may be a cavity formed partially through a first surface of a base substrate, such that the perforation does not open at a second surface, opposite to the first surface, of the base substrate.

Slot: A slot is an electrically-conductive strip, formed over a base substrate, to facilitate placing of electrical components.

Embedded connector: An embedded connector is an electrically-conductive arrangement embedded in a base substrate.

Bond pad: A bond pad is a pad, made of an electrically-conductive material, formed over a base substrate. The bond pad provides an interface to connect electrical components to embedded connectors.

Electrical connector: An electrical connector is a thin wire made of an electrically-conductive material for electrically connecting two points.

Electrical component: An electrical component is a component of an electronic device, and is placed on appropriate slots on a base substrate to achieve the objective of the electronic device.

Molding material: A molding material is a material that may be molded in any desired form. In an embodiment herein, a molding material is molded over a first surface of a base substrate, such that the molding material fills in and adheres to perforations formed on the base substrate. The molding material may, for example, include at least one of: epoxy resin, silicone, acrylic and polyurethane.

Affinitive material: An affinitive material is a material having an affinity for a molding material. The affinitive material may, for example, include at least one of: silver, silver alloy, copper, copper alloy, nickel, nickel alloy, palladium, gold, gold alloy, and black oxide.

Chip-On-Board (COB) type device: A COB type device is an electronic device formed by a COB process. A COB process includes directly placing a bare semiconductor die on an electronic substrate, and electrically connecting the bare semiconductor die to appropriate bond pads on the electronic substrate.

Surface Mount Technology (SMT) type device: An SMT type device is an electronic device formed by an SMT process. An SMT process includes mounting an Integrated Circuit (IC) on an electronic substrate.

Base-obtaining unit: A base-obtaining unit is adapted to obtain a base substrate.

Perforation-forming unit: A perforation-forming unit is adapted to form one or more perforations on a substrate.

Coating unit: A coating unit is adapted to form a coat of an affinitive material on one or more perforations formed on a substrate.

Dispensing unit: A dispensing unit is adapted to dispense/print an electrically-conductive paste on one or more slots on a base substrate. The dispensing unit may, for example, include a stencil printer for printing the electrically-conductive paste on the slots.

Component-placing unit: A component-placing unit is adapted to place one or more electrical components on appropriate slots on the base substrate.

Curing unit: A curing unit is adapted to cure the electrically-conductive paste, after the electrical components are placed on the slots.

Connecting unit: A connecting unit is adapted to electrically connect the electrical components in a pre-defined manner through one or more electrical connectors.

Wire-bonding unit: A wire-bonding unit is adapted to wire bond the electrical components with one or more preset bond pads on the base substrate.

Molding unit: A molding unit is adapted to mold a molding material over the base substrate, such that the molding material fills in and adheres to perforations formed on the base substrate.

The method includes forming one or more perforations on a substrate, forming a coat of an affinitive material on at least one of the perforations, and filling the molding material in the perforations. The affinitive material has an affinity for the molding material. Therefore, the molding material adheres to the coat of the affinitive material. In this way, adhesion of the molding material to the substrate is enhanced.

The perforations may, for example, be formed using a drill or other suitable cutting tools. Alternatively, the perforations may be formed using suitable molds during molding of the substrate.

The perforations may be formed in any desired shape and/or size. For example, the perforations may have a shape that is curved, polygonal, or a combination thereof. The size of the perforations may, for example, depend on the size of the substrate. The size of the perforations may also depend on the number, the size and the location of various components to be placed on the substrate. In addition, the size of the perforations may depend on their location on the substrate.

In accordance with an embodiment herein, the perforations are formed at preset locations on the substrate. For example, the perforations may be located at a periphery of the substrate.

In accordance with an embodiment herein, the molding material includes at least one of: epoxy resin, silicone, acrylic and polyurethane. As mentioned above, the affinitive material has an affinity for the molding material. Accordingly, a suitable affinitive material may be chosen depending on the molding material to be used. In accordance with an embodiment herein, the affinitive material includes at least one of: silver, silver alloy, copper, copper alloy, nickel, nickel alloy, palladium, gold, gold alloy, and black oxide.

The above-mentioned method enhances adhesion of a molding material to a substrate, and therefore, may be suitable for various applications. In an embodiment herein, the method may be suitably used in the manufacturing of storage devices, where electrical components placed on an electronic substrate may be encapsulated by the molding material hermetically. In another embodiment herein, the method may be suitably used in the manufacturing of various electronic devices. In yet another embodiment herein, the method may be suitably used in the manufacturing of other articles that require encapsulation of components connected to a base substrate.

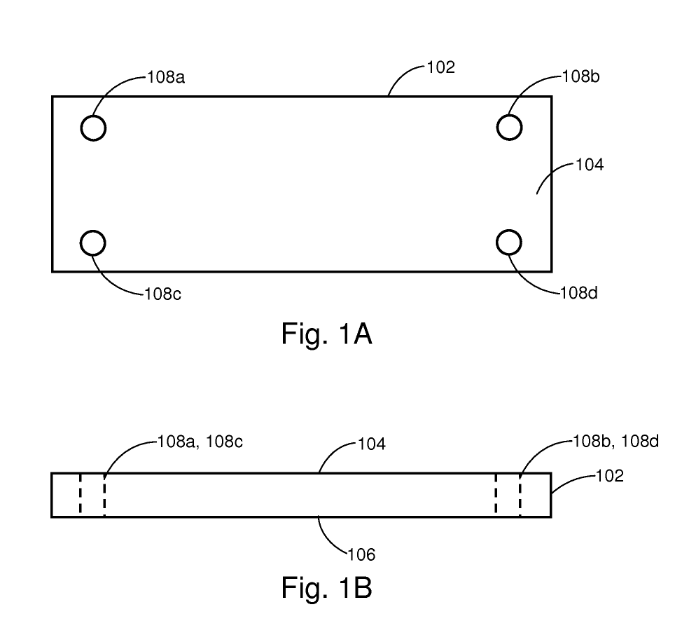

FIGS. 1A and 1B depict top and front views of a base substrate 102, in accordance with an embodiment herein. Base substrate 102 has a first surface 104 and a second surface 106. In accordance with an embodiment herein, base substrate 102 includes one or more perforations, shown as a perforation 108a, a perforation 108b, a perforation 108c and a perforation 108d. Perforation 108a, perforation 108b, perforation 108c and perforation 108d are hereinafter referred as perforations 108. Perforations 108 are capable of facilitating adhesion of a molding material over first surface 104 of base substrate 102.

In accordance with a specific embodiment herein, at least one of perforations 108 is capable of facilitating adhesion of the molding material over second surface 106 of base substrate 102.

In accordance with an embodiment herein, at least one of perforations 108 is coated with a coat of an affinitive material. The affinitive material is a material having an affinity for the molding material. Accordingly, a suitable affinitive material may be chosen depending on the molding material to be used. In accordance with an embodiment herein, the molding material includes at least one of: epoxy resin, silicone, acrylic and polyurethane. In accordance with an embodiment herein, the affinitive material includes at least one of: silver, silver alloy, copper, copper alloy, nickel, nickel alloy, palladium, gold, gold alloy, and black oxide.

In accordance with an embodiment herein, perforations 108 are formed at preset locations on base substrate 102. For example, perforations 108 may be located at a periphery of base substrate 102, as shown in FIG. 1A.

In addition, perforations 108 may be formed in any desired shape and/or size. For example, perforations 108 may have a shape that is curved, polygonal, or a combination thereof. With reference to FIG. 1A, perforations 108 are circular in shape.

The size of perforations 108 may depend on the size of base substrate 102. The size of perforations 108 may also depend on the number, the size and the location of various components to be placed on base substrate 102. In addition, the size of perforations 108 may depend on their location on base substrate 102.

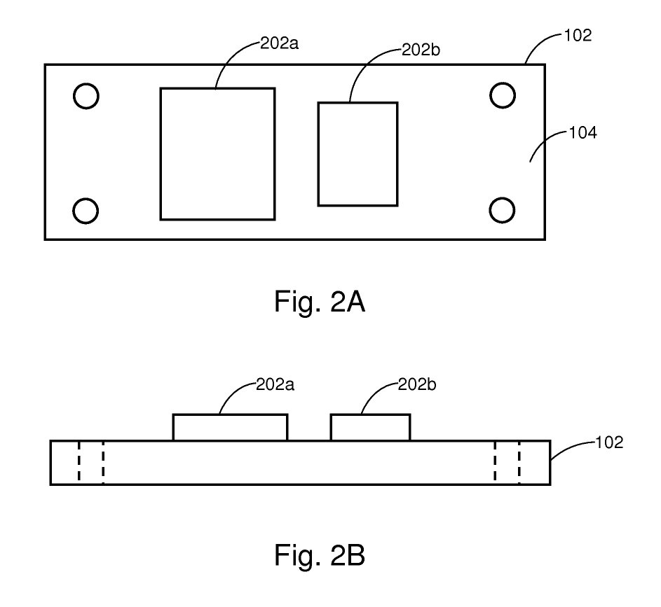

FIGS. 2A and 2B depict top and front views of base substrate 102, in accordance with an embodiment herein. With reference to FIG. 2A, one or more components, shown as a component 202a and a component 202b, are placed on preset locations on base substrate 102. Component 202a and component 202b are hereinafter referred as components 202. Components 202 are connected to base substrate 102, in accordance with an embodiment herein.

Components 202 may, for example, be thermally bonded to base substrate 102 using an electrically-conductive paste.

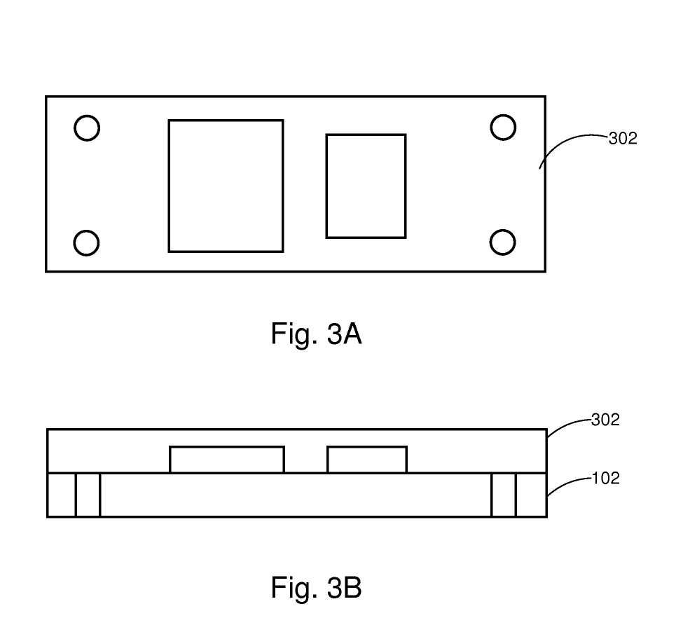

FIGS. 3A and 3B depict top and front views of base substrate 102, in accordance with an embodiment herein. With reference to FIGS. 3A and 3B, a molding material 302 is molded over first surface 104 and components 202. Consequently, molding material 302 fills in and adheres to perforations 108, and encapsulates components 202.

As mentioned above, the affinitive material has an affinity for molding material 302. Therefore, the coat of the affinitive material enhances the adhesion of molding material 302 to base substrate 102. Consequently, molding material 302 encapsulates components 202 hermetically.

In accordance with a specific embodiment herein, molding material 302 is also molded over second surface 106 of base substrate 102.

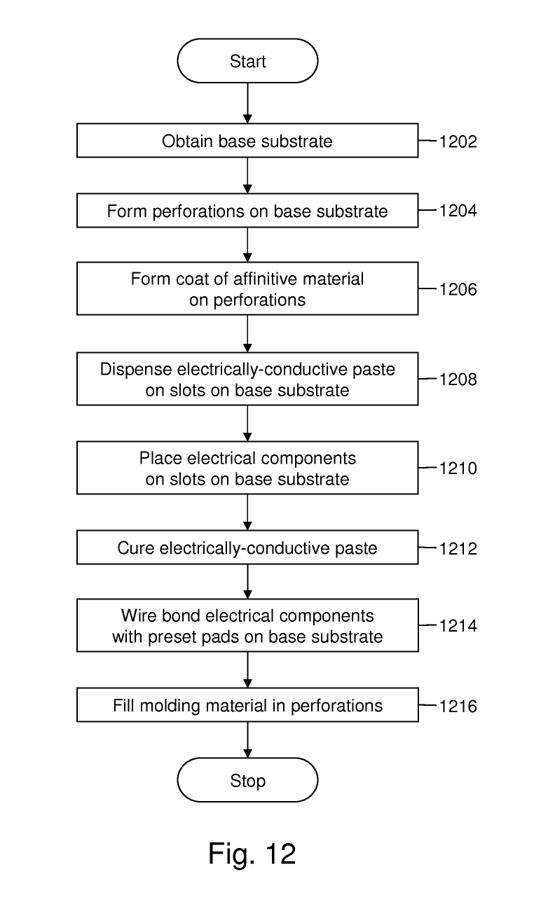

FIGS. 1A-1B, 2A-2B and 3A-3B depict various stages in which an article is manufactured, in accordance with an embodiment herein. In accordance with an embodiment herein, the article is an SMT type device. Consider, for example, that the article is a storage device. In such a case, at least one of components 202 may be a Flash IC. A USB connector may be connected to base substrate 102. Details of how an SMT type device may be manufactured have been provided in conjunction with FIG. 12.

It should be noted here that the article so manufactured is not limited to a specific shape or size of its components. FIGS. 1A-1B, 2A-2B and 3A-3B are merely an example, which should not unduly limit the scope of the claims herein. One of ordinary skill in the art would recognize many variations, alternatives, and modifications of embodiments herein.

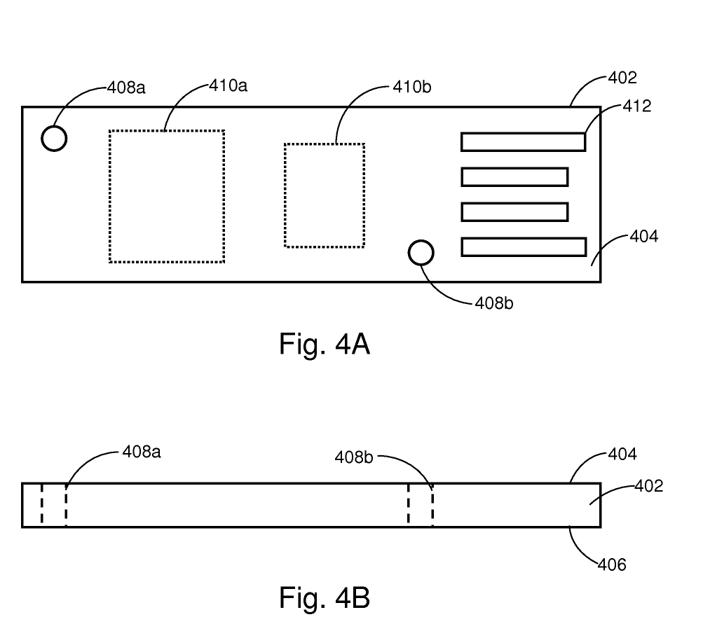

FIGS. 4A and 4B depict top and front views of a base substrate 402, in accordance with another embodiment herein. Base substrate 402 has a first surface 404 and a second surface 406. In accordance with an embodiment herein, base substrate 402 includes one or more perforations, shown as a perforation 408a and a perforation 408b. Perforation 408a and perforation 408b are hereinafter referred as perforations 408. Perforations 408 are capable of facilitating adhesion of a molding material over first surface 404 of base substrate 402.

In accordance with a specific embodiment herein, at least one of perforations 408 is capable of facilitating adhesion of the molding material over second surface 406 of base substrate 402.

In accordance with an embodiment herein, at least one of perforations 408 is coated with a coat of an affinitive material. The affinitive material is a material having an affinity for the molding material. Accordingly, a suitable affinitive material may be chosen depending on the molding material to be used. In accordance with an embodiment herein, the molding material includes at least one of: epoxy resin, silicone, acrylic and polyurethane. In accordance with an embodiment herein, the affinitive material includes at least one of: silver, silver alloy, copper, copper alloy, nickel, nickel alloy, palladium, gold, gold alloy, and black oxide.

In accordance with an embodiment herein, perforations 408 are formed at preset locations on base substrate 402. For example, perforations 408 may be located at a periphery of base substrate 402.

In addition, perforations 408 may be formed in any desired shape and/or size. For example, perforations 408 may have a shape that is curved, polygonal, or a combination thereof. With reference to FIG. 4A, perforations 408 are circular in shape.

The size of perforations 408 may depend on the size of base substrate 402. The size of perforations 408 may also depend on the number, the size and the location of various components to be placed on base substrate 402. In addition, the size of perforations 408 may also depend on their location on base substrate 402.

In accordance with an embodiment herein, base substrate 402 is an electronic substrate that includes one or more slots, shown as a slot 410a and a slot 410b, to facilitate placing of electrical components. Slot 410a and slot 410b are hereinafter referred as slots 410. In accordance with an embodiment herein, at least one of slots 410 is formed on first surface 404 of base substrate 402.

Base substrate 402 also includes one or more embedded connectors (not shown) for electrically connecting electrical components placed on slots 410 in a pre-defined manner, in accordance with an embodiment herein.

In accordance with an embodiment herein, base substrate 402 is an extended PCB that includes one or more conductive strips 412 capable of facilitating a USB connection.

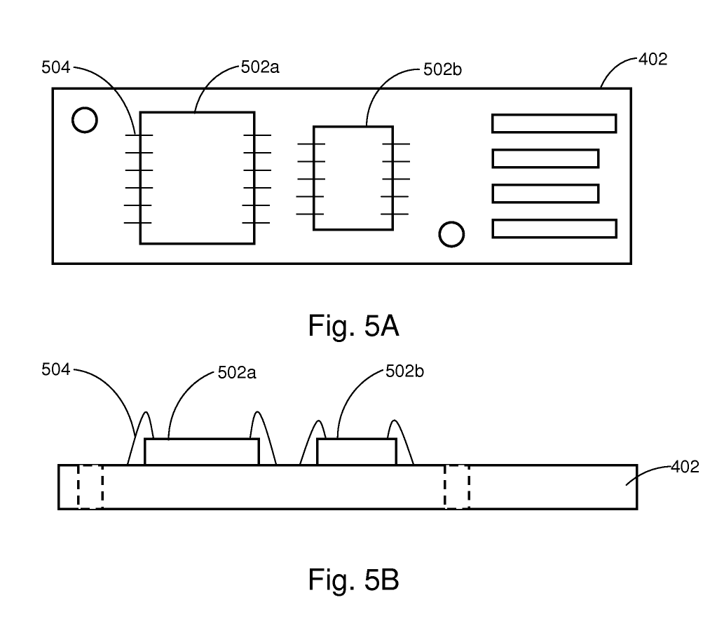

FIGS. 5A and 5B depict top and front views of base substrate 402, in accordance with another embodiment herein. With reference to FIG. 5A, one or more electrical components, shown as an electrical component 502a and an electrical component 502b, are placed on appropriate slots on base substrate 402. Electrical component 502a and electrical component 502b are hereinafter referred as electrical components 502. At least one of electrical components 502 is capable of storing data, in accordance with an embodiment herein.

Electrical components 502 may, for example, be thermally bonded to base substrate 402 using an electrically-conductive paste. In addition, electrical components 502 may be wire bonded to preset bond pads on base substrate 502 using wires 504, as shown in FIG. 5A.

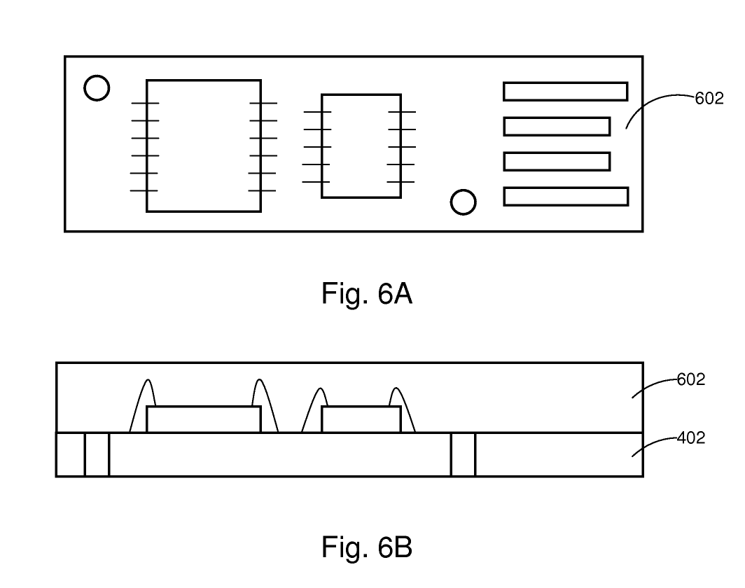

FIGS. 6A and 6B depict top and front views of base substrate 402, in accordance with another embodiment herein. With reference to FIGS. 6A and 6B, a molding material 602 is molded over first surface 404 and electrical components 502. Consequently, molding material 602 fills in and adheres to perforations 408, and encapsulates electrical components 502.

As mentioned above, the affinitive material has an affinity for molding material 602. Therefore, the coat of the affinitive material enhances the adhesion of molding material 602 to base substrate 402. Consequently, molding material 602 encapsulates electrical components 502 hermetically.

In accordance with a specific embodiment herein, molding material 602 is also molded over second surface 406 of base substrate 402.

FIGS. 4A-4B, 5A-5B and 6A-6B depict various stages in which a storage device is manufactured, in accordance with another embodiment herein. In accordance with another embodiment herein, the storage device is a COB type device. Details of how a COB type device may be manufactured have been provided in conjunction with FIG. 12.

It should be noted here that the storage device so manufactured is not limited to a specific shape or size of its components. FIGS. 4A-4B, 5A-5B and 6A-6B are merely an example, which should not unduly limit the scope of the claims herein. One of ordinary skill in the art would recognize many variations, alternatives, and modifications of embodiments herein.

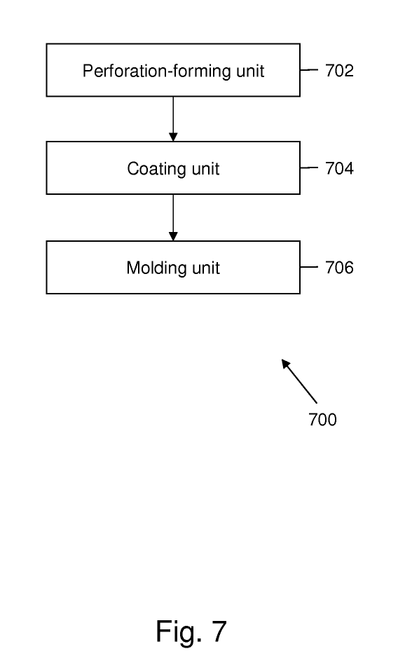

FIG. 7 depicts a system 700 for enhancing adhesion of a molding material with a substrate, in accordance with an embodiment herein. System 700 includes a perforation-forming unit 702, a coating unit 704 and a molding unit 706.

Perforation-forming unit 702 is adapted to form one or more perforations on the substrate. In an embodiment herein, perforation-forming unit 702 includes a drill adapted to mechanically drill the perforations through the substrate. In an alternative embodiment herein, the perforations may be drilled partially through a first surface of the substrate, such that the perforations do not open at a second surface, opposite to the first surface, of the substrate. Perforation-forming unit 702 may be automated and controlled by a drill file that describes the location, size and/or shape of each perforation. Alternatively, perforation-forming unit 702 may include other suitable cutting tools.

In another embodiment herein, perforation-forming unit 702 is an injection molding machine adapted to mold a substrate of a desired shape and size along with perforations at desired locations and of desired shape and size. Accordingly, the perforations may be formed using suitable molds during molding of the substrate.

Coating unit 704 is adapted to form a coat of an affinitive material on at least one of the perforations. As mentioned above, the affinitive material is a material having an affinity for the molding material. Coating unit 704 may, for example, be adapted to choose a suitable affinitive material depending on the molding material to be used. In accordance with an embodiment herein, the molding material includes at least one of: epoxy resin, silicone, acrylic and polyurethane. In accordance with an embodiment herein, the affinitive material includes at least one of: silver, silver alloy, copper, copper alloy, nickel, nickel alloy, palladium, gold, gold alloy, and black oxide.

In an embodiment herein, the walls of the perforations are plated with the affinitive material. In a specific embodiment herein, the perforations are etched using, for example, plasma-etching before the perforations are plated.

In addition, coating unit 704 may be adapted to control the thickness of the coat of the affinitive material. For example, the thickness of the coat may range from 20 mil to 60 mil (one mil is equal to one thousand of an inch).

Molding unit 706 is adapted to mold the molding material over the substrate, such that the molding material fills in the perforations. Consequently, the molding material adheres to the coat of the affinitive material on the perforations.

Molding unit 706 may, for example, be a transfer molding machine adapted to mold the molding material over the substrate.

In accordance with an embodiment herein, the substrate is capable of sustaining compressive forces applied during molding. Accordingly, the substrate may, for example, be made of a material with specific physical properties. Some of these physical properties may depend on the physical dimensions of the substrate. Accordingly, a substrate of specific dimensions may be used. In one example, the substrate is a PCB. In such a case, the thickness of the PCB may, for example, range from 0.2 mm to 0.8 mm.

FIG. 7 is merely an example, which should not unduly limit the scope of the claims herein. One of ordinary skill in the art would recognize many variations, alternatives, and modifications of embodiments herein.

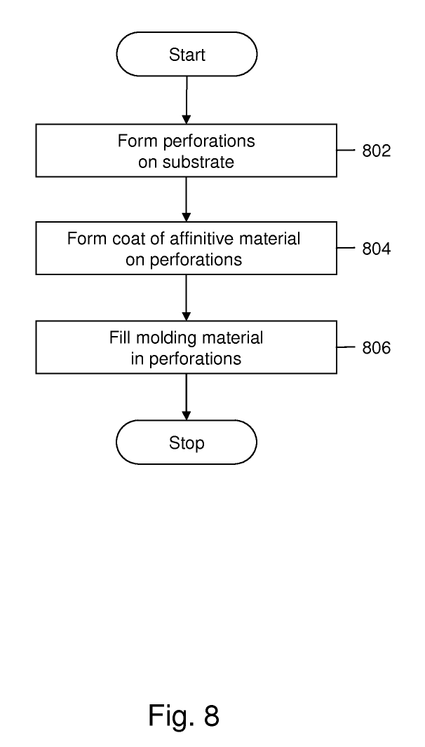

FIG. 8 illustrates a method of enhancing adhesion of a molding material with a substrate, in accordance with an embodiment herein. The method is illustrated as a collection of steps in a logical flow diagram, which represents a sequence of steps that can be implemented in hardware, software, or a combination thereof.

At step 802, one or more perforations are formed on the substrate. In an embodiment herein, step 802 may be performed by a drill adapted to mechanically drill the perforations through the substrate. In an alternative embodiment herein, the perforations may be drilled partially through a first surface of the substrate, such that the perforations do not open at a second surface, opposite to the first surface, of the substrate. In addition, the drill may be automated and controlled by a drill file that describes the location, size and/or shape of each perforation. In another embodiment herein, step 802 may be performed by an injection molding machine adapted to mold a substrate of a desired shape and size along with perforations at desired locations and of desired shape and size. Accordingly, the perforations may be formed using suitable molds during molding of the substrate.

At step 804, a coat of an affinitive material is formed on at least one of the perforations. As mentioned above, the affinitive material is a material having an affinity for the molding material. Therefore, a suitable affinitive material may be chosen depending on the molding material to be used. In accordance with an embodiment herein, the molding material includes at least one of: epoxy resin, silicone, acrylic and polyurethane. In accordance with an embodiment herein, the affinitive material includes at least one of: silver, silver alloy, copper, copper alloy, nickel, nickel alloy, palladium, gold, gold alloy, and black oxide.

In an embodiment herein, step 804 includes plating the walls of the perforations with the affinitive material. In a specific embodiment herein, an optional step of etching the perforations may be performed before step 804. The optional step may, for example, be performed using plasma-etching.

In addition, step 804 may include a sub-step of controlling the thickness of the coat of the affinitive material. For example, the thickness of the coat may range from 20 mil to 60 mil.

At step 806, the molding material is molded over the substrate, such that the molding material fills in the perforations. Consequently, the molding material adheres to the coat of the affinitive material on the perforations. Step 806 may, for example, be performed by a transfer molding machine adapted to mold the molding material over the substrate.

In accordance with an embodiment herein, the substrate is capable of sustaining compressive forces applied during molding. Accordingly, the substrate may, for example, be made of a material with specific physical properties. Some of these physical properties may depend on the physical dimensions of the substrate. Accordingly, a substrate of specific dimensions may be used. In one example, the substrate is a PCB. In such a case, the thickness of the PCB may, for example, range from 0.2 mm to 0.8 mm.

It should be noted here that steps 802-806 are only illustrative and other alternatives can also be provided where steps are added, one or more steps are removed, or one or more steps are provided in a different sequence without departing from the scope of the claims herein. For example, one or more of the following steps may be added: the step of placing one or more components on the substrate, the step of connecting the components to the substrate, and the step of encapsulating the components in the molding material.

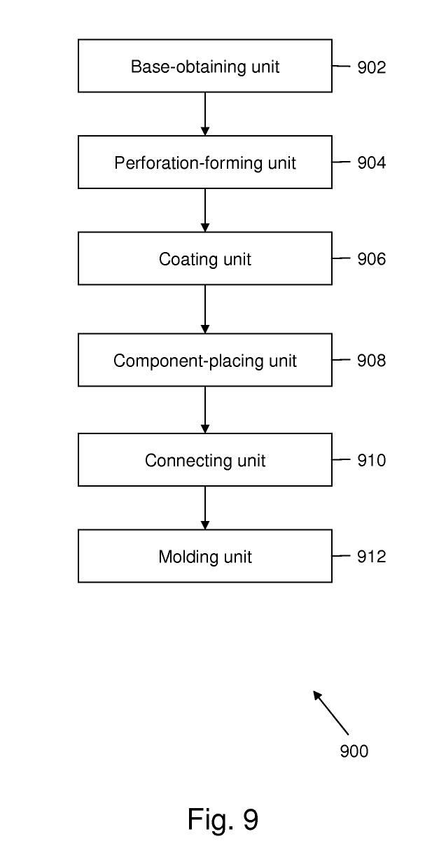

FIG. 9 depicts a system 900 for manufacturing a storage device, in accordance with an embodiment herein. System 900 includes a base-obtaining unit 902, a perforation-forming unit 904, a coating unit 906, a component-placing unit 908, a connecting unit 910 and a molding unit 912.

Base-obtaining unit 902 is adapted to obtain a base substrate. The base substrate includes a first surface and a second surface. The base substrate may include one or more slots to facilitate placing of electrical components. In accordance with an embodiment herein, at least one of these slots is formed on the first surface of the base substrate. The base substrate may also include one or more embedded connectors for electrically connecting electrical components placed on the slots in a pre-defined manner, in accordance with an embodiment herein.

Perforation-forming unit 904 is adapted to form one or more perforations on the base substrate. In an embodiment herein, perforation-forming unit 904 includes a drill adapted to mechanically drill the perforations through the base substrate. In an alternative embodiment herein, the perforations may be drilled partially through the first surface of the base substrate, such that the perforations do not open at the second surface of the base substrate. Perforation-forming unit 904 may be automated and controlled by a drill file that describes the location, size and/or shape of each perforation. Alternatively, perforation-forming unit 904 may include other suitable cutting tools.

In another embodiment herein, base-obtaining unit 902 and perforation-forming unit 904 are implemented together in the form of an injection molding machine adapted to mold a base substrate of a desired shape and size along with perforations at desired locations and of desired shape and size. Accordingly, the perforations may be formed using suitable molds during molding of the base substrate.

Coating unit 906 is adapted to form a coat of an affinitive material on at least one of the perforations. As mentioned above, the affinitive material is a material having an affinity for the molding material. Coating unit 906 may, for example, be adapted to choose a suitable affinitive material depending on the molding material to be used. In accordance with an embodiment herein, the molding material includes at least one of: epoxy resin, silicone, acrylic and polyurethane. In accordance with an embodiment herein, the affinitive material includes at least one of: silver, silver alloy, copper, copper alloy, nickel, nickel alloy, palladium, gold, gold alloy, and black oxide.

In an embodiment herein, the walls of the perforations are plated with the affinitive material. In a specific embodiment herein, the perforations are etched using, for example, plasma-etching before the perforations are plated.

In addition, coating unit 906 may be adapted to control the thickness of the coat of the affinitive material. For example, the thickness of the coat may range from 20 mil to 60 mil.

Component-placing unit 908 is adapted to place one or more electrical components on the slots on the base substrate. At least one of these electrical components is capable of storing data, in accordance with an embodiment herein. Component-placing unit 908 may, for example, be a pick-and-place unit that is programmed to pick electrical components and place them on appropriate slots on a base substrate.

Connecting unit 910 is adapted to electrically connect the electrical components in a pre-defined manner through one or more electrical connectors.

Molding unit 912 is adapted to mold the molding material over the first surface of the base substrate, such that the molding material fills in and adheres to the perforations. Consequently, the molding material encapsulates the electrical components and the electrical connectors hermetically. Molding unit 912 may, for example, be a transfer molding machine adapted to mold the molding material over the first surface of the base substrate. In an alternative embodiment herein, the molding material is molded over both the first surface and the second surface of the base substrate.

In accordance with an embodiment herein, the base substrate is capable of sustaining compressive forces applied during molding. Accordingly, the base substrate may, for example, be made of a material with specific physical properties. Some of these physical properties may depend on the physical dimensions of the base substrate. Accordingly, a base substrate of specific dimensions may be used for manufacturing the storage device. In one example, the base substrate is a PCB. In such a case, the thickness of the PCB may, for example, range from 0.2 mm to 0.8 mm.

FIG. 9 is merely an example, which should not unduly limit the scope of the claims herein. One of ordinary skill in the art would recognize many variations, alternatives, and modifications of embodiments herein.

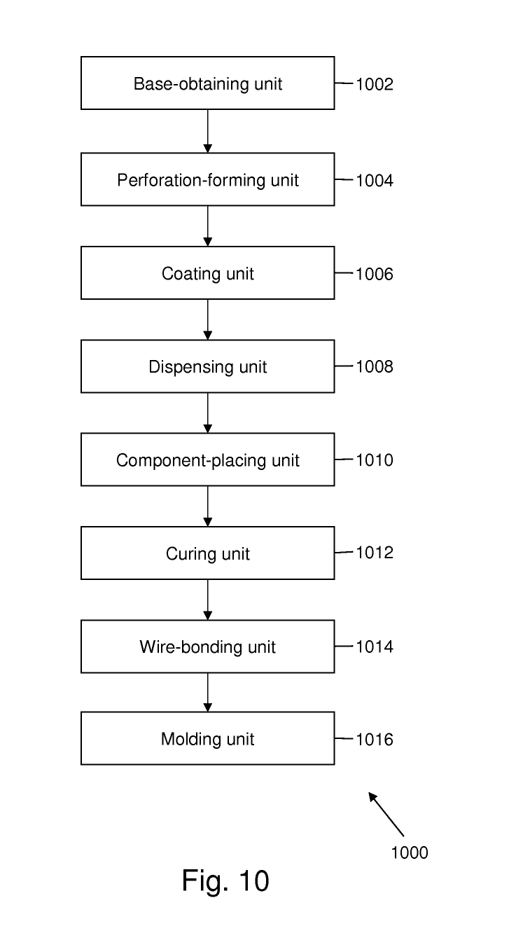

FIG. 10 depicts a system 1000 for manufacturing a storage device, in accordance with another embodiment herein. System 1000 includes a base-obtaining unit 1002, a perforation-forming unit 1004, a coating unit 1006, a dispensing unit 1008, a component-placing unit 1010, a curing unit 1012, a wire-bonding unit 1014 and a molding unit 1016.

Base-obtaining unit 1002 is adapted to obtain a base substrate. The base substrate includes a first surface and a second surface. The base substrate may include one or more slots to facilitate placing of electrical components. In accordance with an embodiment herein, at least one of these slots is formed on the first surface of the base substrate. The base substrate may also include one or more embedded connectors for electrically connecting electrical components placed on the slots in a pre-defined manner, in accordance with an embodiment herein.

Perforation-forming unit 1004 is adapted to form one or more perforations on the base substrate. In an embodiment herein, perforation-forming unit 1004 includes a drill adapted to mechanically drill the perforations through the base substrate. In an alternative embodiment herein, the perforations may be drilled partially through the first surface of the base substrate, such that the perforations do not open at the second surface of the base substrate. Perforation-forming unit 1004 may be automated and controlled by a drill file that describes the location, size and/or shape of each perforation. Alternatively, perforation-forming unit 1004 may include other suitable cutting tools.

In another embodiment herein, base-obtaining unit 1002 and perforation-forming unit 1004 are implemented together in the form of an injection molding machine adapted to mold a base substrate of a desired shape and size along with perforations at desired locations and of desired shape and size. Accordingly, the perforations may be formed using suitable molds during molding of the base substrate.

Coating unit 1006 is adapted to form a coat of an affinitive material on at least one of the perforations. As mentioned above, the affinitive material is a material having an affinity for the molding material. Coating unit 1006 may, for example, be adapted to choose a suitable affinitive material depending on the molding material to be used. In accordance with an embodiment herein, the molding material includes at least one of: epoxy resin, silicone, acrylic and polyurethane. In accordance with an embodiment herein, the affinitive material includes at least one of: silver, silver alloy, copper, copper alloy, nickel, nickel alloy, palladium, gold, gold alloy, and black oxide.

In an embodiment herein, the walls of the perforations are plated with the affinitive material. In a specific embodiment herein, the perforations are etched using, for example, plasma-etching before the perforations are plated.

In addition, coating unit 1006 may be adapted to control the thickness of the coat of the affinitive material. For example, the thickness of the coat may range from 20 mil to 60 mil.

Dispensing unit 1008 is adapted to dispense an electrically-conductive paste on the slots on the base substrate.

Component-placing unit 1010 is adapted to place one or more electrical components on the slots on the base substrate. At least one of these electrical components is capable of storing data, in accordance with an embodiment herein. Component-placing unit 1010 may, for example, be a pick-and-place unit that is programmed to pick electrical components and place them on appropriate slots on a base substrate.

Curing unit 1012 is adapted to cure the electrically-conductive paste. Curing unit 1012 may, for example, include an oven in which the base substrate with the placed electrical components may be heated to a preset temperature for a preset duration.

Wire-bonding unit 1014 is adapted to wire bond the electrical components with one or more preset bond pads on the base substrate. Wire-bonding unit 1014 may, for example, implement thermo-sonic compression bonding using gold wires. In such a case, the base substrate is heated to a preset temperature to connect the gold wires to the electrical components and to the bond pads on the base substrate. In an additional embodiment herein, system 1000 includes a cleaning unit adapted to clean the bond pads on the base substrate, before wire bonding. The cleaning unit may, for example, use plasma cleaning.

Molding unit 1016 is adapted to mold the molding material over the first surface of the base substrate, such that the molding material fills in and adheres to the perforations. Consequently, the molding material encapsulates the electrical components and the electrical connectors hermetically. Molding unit 1016 may, for example, be a transfer molding machine adapted to mold the molding material over the first surface of the base substrate. In an alternative embodiment herein, the molding material is molded over both the first surface and the second surface of the base substrate.

In accordance with an embodiment herein, the base substrate is capable of sustaining compressive forces applied during molding. Accordingly, the base substrate may, for example, be made of a material with specific physical properties. Some of these physical properties may depend on the physical dimensions of the base substrate. Accordingly, a base substrate of specific dimensions may be used for manufacturing the storage device. In one example, the base substrate is a PCB. In such a case, the thickness of the PCB may, for example, range from 0.2 mm to 0.8 mm.

FIG. 10 is merely an example, which should not unduly limit the scope of the claims herein. One of ordinary skill in the art would recognize many variations, alternatives, and modifications of embodiments herein.

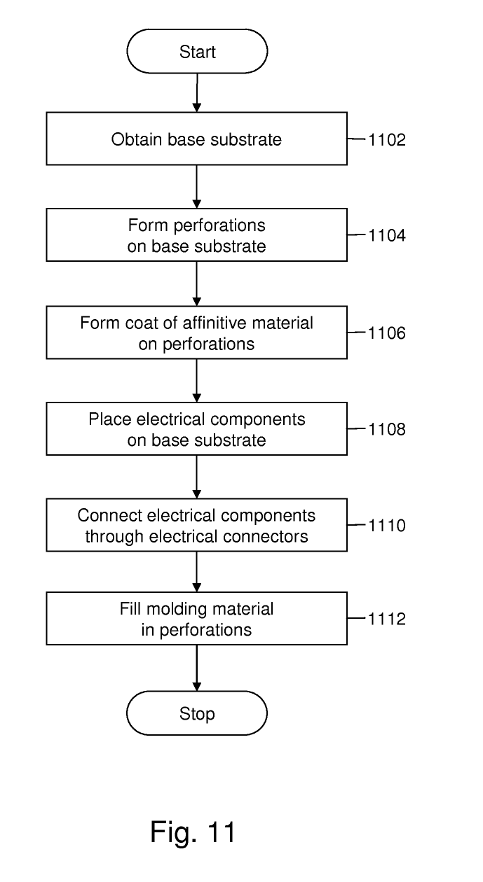

FIG. 11 depicts a method of manufacturing a storage device, in accordance with an embodiment herein. The method is illustrated as a collection of steps in a logical flow diagram, which represents a sequence of steps that can be implemented in hardware, software, or a combination thereof.

At step 1102, a base substrate is obtained. The base substrate includes a first surface and a second surface. The base substrate may include one or more slots to facilitate placing of electrical components. In accordance with an embodiment herein, at least one of these slots is formed on the first surface of the base substrate. The base substrate may also include one or more embedded connectors for electrically connecting electrical components placed on the slots in a pre-defined manner, in accordance with an embodiment herein.

At step 1104, one or more perforations are formed on the base substrate. In an embodiment herein, step 1104 is performed by a drill adapted to mechanically drill the perforations through the base substrate. In an alternative embodiment herein, the perforations may be drilled partially through the first surface of the base substrate, such that the perforations do not open at the second surface of the base substrate. In addition, the drill may be automated and controlled by a drill file that describes the location, size and/or shape of each perforation. Alternatively, step 1104 may be performed by other suitable cutting tools.

In another embodiment herein, step 1102 and step 1104 may be performed together by an injection molding machine adapted to mold a base substrate of a desired shape and size along with perforations at desired locations and of desired shape and size. Accordingly, the perforations may be formed using suitable molds during molding of the base substrate.

At step 1106, a coat of an affinitive material is formed on at least one of the perforations. As mentioned above, the affinitive material is a material having an affinity for the molding material. Therefore, a suitable affinitive material may be chosen depending on the molding material to be used. In accordance with an embodiment herein, the molding material includes at least one of: epoxy resin, silicone, acrylic and polyurethane. In accordance with an embodiment herein, the affinitive material includes at least one of: silver, silver alloy, copper, copper alloy, nickel, nickel alloy, palladium, gold, gold alloy, and black oxide.

In an embodiment herein, step 1106 includes plating the walls of the perforations with the affinitive material. In a specific embodiment herein, an optional step of etching the perforations may be performed before step 1106. The optional step may, for example, be performed using plasma-etching.

In addition, step 1106 may include a sub-step of controlling the thickness of the coat of the affinitive material. For example, the thickness of the coat may range from 20 mil to 60 mil.

At step 1108, one or more electrical components are placed on the slots on the base substrate. At least one of these electrical components is capable of storing data, in accordance with an embodiment herein.

Step 1108 may, for example, be performed by a pick-and-place unit that is programmed to pick electrical components and place them on appropriate slots on a base substrate.

At step 1110, the electrical components are electrically connected in a pre-defined manner through one or more electrical connectors.

At step 1112, the molding material is molded over the first surface of the base substrate, such that the molding material fills in and adheres to the perforations. Consequently, the molding material encapsulates the electrical components and the electrical connectors hermetically.

Step 1112 may, for example, be performed by a transfer molding machine adapted to mold the molding material over the first surface of the base substrate. In an alternative embodiment herein, the molding material is molded over both the first surface and the second surface of the base substrate.

In accordance with an embodiment herein, the base substrate is capable of sustaining compressive forces applied during molding at step 1112. Accordingly, the base substrate may, for example, be made of a material with specific physical properties. Some of these physical properties may depend on the physical dimensions of the base substrate. Accordingly, a base substrate of specific dimensions may be used for manufacturing the storage device. In one example, the base substrate is a PCB. In such a case, the thickness of the PCB may, for example, range from 0.2 mm to 0.8 mm.

It should be noted here that steps 1102-1112 are only illustrative and other alternatives can also be provided where steps are added, one or more steps are removed, or one or more steps are provided in a different sequence without departing from the scope of the claims herein.

FIG. 12 depicts a method of manufacturing a storage device, in accordance with another embodiment herein. The method is illustrated as a collection of steps in a logical flow diagram, which represents a sequence of steps that can be implemented in hardware, software, or a combination thereof.

At step 1202, a base substrate is obtained. The base substrate includes a first surface and a second surface. The base substrate may include one or more slots to facilitate placing of electrical components. In accordance with an embodiment herein, at least one of these slots is formed on the first surface of the base substrate. The base substrate may also include one or more embedded connectors for electrically connecting electrical components placed on the slots in a pre-defined manner, in accordance with an embodiment herein.

At step 1204, one or more perforations are formed on the base substrate. In an embodiment herein, step 1204 is performed by a drill adapted to mechanically drill the perforations through the base substrate. In an alternative embodiment herein, the perforations may be drilled partially through the first surface of the base substrate, such that the perforations do not open at the second surface of the base substrate. In addition, the drill may be automated and controlled by a drill file that describes the location, size and/or shape of each perforation. Alternatively, step 1204 may be performed by other suitable cutting tools.

In another embodiment herein, step 1202 and step 1204 may be performed together by an injection molding machine adapted to mold a base substrate of a desired shape and size along with perforations at desired locations and of desired shape and size. Accordingly, the perforations may be formed using suitable molds during molding of the base substrate.

At step 1206, a coat of an affinitive material is formed on at least one of the perforations. As mentioned above, the affinitive material is a material having an affinity for the molding material. Therefore, a suitable affinitive material may be chosen depending on the molding material to be used. In accordance with an embodiment herein, the molding material includes at least one of: epoxy resin, silicone, acrylic and polyurethane. In accordance with an embodiment herein, the affinitive material includes at least one of: silver, silver alloy, copper, copper alloy, nickel, nickel alloy, palladium, gold, gold alloy, and black oxide.

In an embodiment herein, step 1206 includes plating the walls of the perforations with the affinitive material. In a specific embodiment herein, an optional step of etching the perforations may be performed before step 1206. The optional step may, for example, be performed using plasma-etching.

In addition, step 1206 may include a sub-step of controlling the thickness of the coat of the affinitive material. For example, the thickness of the coat may range from 20 mil to 60 mil.

At step 1208, an electrically-conductive paste is dispensed on the slots on the base substrate.

At step 1210, one or more electrical components are placed on the slots on the base substrate. At least one of these electrical components is capable of storing data, in accordance with an embodiment herein. Step 1210 may, for example, be performed by a pick-and-place unit that is programmed to pick electrical components and place them on appropriate slots on a base substrate.

At step 1212, the electrically-conductive paste is cured. Step 1212 may, for example, be performed in an oven, where the base substrate with the placed electrical components may be heated to a preset temperature for a preset duration.

At step 1214, the electrical components are wire-bonded with one or more preset bond pads on the base substrate. Step 1214 may, for example, be performed by thermo-sonic compression bonding using gold wires. In such a case, the base substrate is heated to a preset temperature to connect the gold wires to the electrical components and to the bond pads on the base substrate. In an additional embodiment herein, an optional step of cleaning the bond pads may be performed before step 1214. The optional step may, for example, be performed by plasma cleaning.

At step 1216, the molding material is molded over the first surface of the base substrate, such that the molding material fills in and adheres to the perforations. Consequently, the molding material encapsulates the electrical components and the electrical connectors hermetically.

Step 1216 may, for example, be performed by a transfer molding machine adapted to mold the molding material over the first surface of the base substrate. In an alternative embodiment herein, the molding material is molded over both the first surface and the second surface of the base substrate.

In accordance with an embodiment herein, the base substrate is capable of sustaining compressive forces applied during molding at step 1216. Accordingly, the base substrate may, for example, be made of a material with specific physical properties. Some of these physical properties may depend on the physical dimensions of the base substrate. Accordingly, a base substrate of specific dimensions may be used for manufacturing the storage device. In one example, the base substrate is a PCB. In such a case, the thickness of the PCB may, for example, range from 0.2 mm to 0.8 mm.

It should be noted here that steps 1202-1216 are only illustrative and other alternatives can also be provided where steps are added, one or more steps are removed, or one or more steps are provided in a different sequences without departing from the scope of the claims herein. In accordance with an embodiment herein, steps 1202-1216 may be performed on a panel including a plurality of base substrates. In such a case, an additional step of de-panelizing individual base substrates may be performed after step 1216. The step of de-panelizing may, for example, be performed by a laser-cutting device.

In an embodiment herein, an SMT type storage device is manufactured using an SMT process. In accordance with step 1202, a base substrate of 0.8 mm thickness is obtained. The base substrate may, for example, be a PCB including one or more slots to facilitate placing of electrical components, and one or more embedded connectors for electrically connecting electrical components placed on these slots in a pre-defined manner.

In accordance with step 1204, one or more perforations are formed on the base substrate. The perforations may, for example, be formed at pre-defined locations on the base substrate and of pre-defined size and/or shape. For example, the size of the perforations may range from 1 mm to 4 mm.

In accordance with step 1206, the perforations are plated with an affinitive material, for example, silver.

Next, in accordance with step 1208, a solder paste is dispensed on the slots on the base substrate. Subsequently, in accordance with step 1210, one or more electrical components are placed on the slots on the base substrate. One of these electrical components may, for example, be a Flash IC. Accordingly, a USB connector may be connected to the base substrate to facilitate USB connectivity.

In accordance with step 1212, the solder paste may be cured, for example, in an environment, where the base substrate with the placed electrical components may be heated to a preset temperature. Accordingly, the solder paste melts and holds the electrical components on their slots.

In accordance with step 1216, an epoxy molding compound may, for example, be transfer molded over the electrical components and the base substrate. Accordingly, the epoxy molding compound fills in and adheres to the perforations, thereby encapsulating the electrical components hermetically. The epoxy molding compound protects the electrical components from mechanical and chemical damage.

Finally, the storage device so manufactured may be cased in a casing, in order to protect the storage device from external factors, such as heat, moisture and scratches. The casing may be attached to the base substrate and/or the molded epoxy molding compound, for example, through a gluing process or an ultrasonic welding process.

In another embodiment herein, a COB type storage device is manufactured using a COB process. In accordance with step 1202, a base substrate of 0.4 mm thickness is obtained. The base substrate may, for example, be an extended PCB that includes one or more conductive strips capable of facilitating a USB connection. The base substrate may include one or more slots to facilitate placing of electrical components, and one or more embedded connectors for electrically connecting electrical components placed on these slots in a pre-defined manner.

In accordance with step 1204, one or more perforations are formed on the base substrate. The perforations may, for example, be formed at pre-defined locations on the base substrate and of pre-defined size and/or shape. For example, the size of the perforations may range from 1 mm to 4 mm.

In accordance with step 1206, the perforations are coated with an affinitive material, for example, silver.

Next, in accordance with step 1208, a solder paste is dispensed on at least one slot on the base substrate. Subsequently, in accordance with step 1210, at least one SMT component is placed on the at least one slot on the base substrate.

At step 1212, the solder paste may be cured, for example, in an environment, where the base substrate with the at least one SMT component may be heated to a preset temperature. Accordingly, the solder paste melts and holds the at least one SMT component on the base substrate.

In accordance with step 1208, a silver epoxy paste is dispensed on at least one slot on the base substrate. Subsequently, in accordance with step 1210, a bare semiconductor chip is placed on the at least one slot on the base substrate.

In accordance with step 1212, the silver epoxy paste is cured, for example, in an oven, where the base substrate with the placed electrical components may be heated to a preset temperature for a preset duration.

In accordance with step 1214, the bare semiconductor chip is wire-bonded with one or more preset bond pads on the base substrate. Step 1214 may, for example, be performed by thermo-sonic compression bonding using gold wires. In such a case, the base substrate is heated to a preset temperature to connect the gold wires to the bare semiconductor chip and to the bond pads on the base substrate.

In accordance with step 1216, an epoxy molding compound may, for example, be transfer molded over the at least one SMT component, the bare semiconductor die and the gold wires. Accordingly, the epoxy molding compound fills in and adheres to the perforations, thereby encapsulating the at least one SMT component, the bare semiconductor die and the gold wires hermetically. The epoxy molding compound protects the at least one SMT component, the bare semiconductor die and the gold wires from mechanical and chemical damage.

Finally, the storage device so manufactured may be cased in a casing, in order to protect the storage device from external factors, such as heat, moisture and scratches. The casing may be attached to the base substrate and/or the molded epoxy molding compound, for example, through a gluing process or an ultrasonic welding process.

Embodiments herein provide a method of enhancing adhesion of a molding material with a substrate, and articles manufactured thereof. In an embodiment herein, the method may be suitably used in the manufacturing of storage devices, where electrical components placed on an electronic substrate are encapsulated by a molding material hermetically. The molding material protects the electrical components from mechanical and chemical damage. This makes the storage device highly reliable, shock resistant, water resistant and robust.

In another embodiment herein, the method may be suitably used in the manufacturing of various electronic devices.

In yet another embodiment herein, the method may be suitably used in the manufacturing of other articles that require encapsulation of components connected to a base substrate.

In one embodiment herein, a COB type storage device is manufactured by a COB process. As the COB process requires less space, a base substrate of a small size may be used. The COB type storage device so manufactured is miniature in size. For example, the dimensions of the COB type storage device may be as follows: length ranging from 20 mm to 30 mm, width ranging from 10 mm to 15 mm, and height ranging from 1 mm to 2 mm. Such a miniaturized COB type storage device is easy to handle and use.

Consequently, the COB type storage device may be designed in several forms, due to its miniature size and robustness. In one example, the COB type storage device may be designed in the form of a small-sized chip that may be carried in a wallet. In another example, the COB type storage device may be designed in the form of a key ring that is easy to carry.

Moreover, the storage capacity of the COB type storage device may be increased without changing the overall dimensions of its casing.

Furthermore, the cost of manufacture is reduced, as small-sized base substrates and bare semiconductor dies are used.

This application may disclose several numerical range limitations that support any range within the disclosed numerical ranges even though a precise range limitation is not stated verbatim in the specification because the embodiments of the invention could be practiced throughout the disclosed numerical ranges. Finally, the entire disclosure of the patents and publications referred in this application, if any, are hereby incorporated herein in entirety by reference.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed as being new and desired to be protected by Letters Patent of the United States is as follows:

1. A storage device comprising:
a base substrate comprising a first surface and a second surface, said base substrate further comprising one or more perforations capable of facilitating adhesion of a molding material over said first surface;
one or more electrical components placed on said first surface of said base substrate, at least one of said electrical components being capable of storing data; and
a molding material molded over said first surface, wherein said molding material fills in and adheres to said perforations, and encapsulates said electrical components.

2. The storage device of claim 1, wherein at least one of said perforations is capable of facilitating adhesion of said molding material over said second surface, and wherein said molding material is molded over said second surface.

3. The storage device of claim 1, wherein at least one of said perforations is coated with an affinitive material, said affinitive material having an affinity for said molding material, said affinitive material comprising at least one of: silver, silver alloy, copper, copper alloy, nickel, nickel alloy, palladium, gold, gold alloy, and black oxide.

4. The storage device of claim 1, wherein said perforations are curved in shape.

5. The storage device of claim 1, wherein said perforations are polygonal in shape.

6. The storage device of claim 1, wherein said perforations are located at a periphery of said base substrate.

7. The storage device of claim 1, wherein said base substrate comprises an extended Printed Circuit Board (PCB), said extended PCB comprising one or more conductive strips capable of facilitating a Universal Serial Bus (USB) connection.

8. The storage device of claim 1 is a Chip-On-Board (COB) type device.

9. The storage device of claim 1 is a Surface Mount Technology (SMT) type device.

10. An article comprising:
a base substrate comprising a first surface and a second surface, said base substrate further comprising one or more perforations capable of facilitating adhesion of a molding material over said first surface;
one or more components placed on said first surface of said base substrate; and
a molding material molded over said first surface, wherein said molding material fills in and adheres to said perforations, and encapsulates said components.

11. The article of claim 10, wherein at least one of said perforations is capable of facilitating adhesion of said molding material over said second surface, and wherein said molding material is molded over said second surface.

12. The article of claim 10, wherein at least one of said perforations is coated with an affinitive material, said affinitive material having an affinity for said molding material, said affinitive material comprising at least one of: silver, silver alloy, copper, copper alloy, nickel, nickel alloy, palladium, gold, gold alloy, and black oxide.

13. The article of claim 10, wherein said perforations are curved in shape.

14. The article of claim 10, wherein said perforations are polygonal in shape.

15. The article of claim 10, wherein said perforations are located at a periphery of said base substrate.

16. The article of claim 10 is a Chip-On-Board (COB) type device.

17. The article of claim 10 is a Surface Mount Technology (SMT) type device.

18. A method of enhancing adhesion of a molding material with a substrate, said method comprising:
forming one or more perforations on said substrate;
forming a coat of an affinitive material on at least one of said perforations, said affinitive material having an affinity for said molding material; and
filling said molding material in said perforations, wherein said molding material adheres to said coat of said affinitive material.

19. The method of claim 18, wherein said affinitive material comprises at least one of: silver, silver alloy, copper, copper alloy, nickel, nickel alloy, palladium, gold, gold alloy, and black oxide.

20. The method of claim 18, wherein said filling comprises transfer molding said molding material over said substrate.
